(19) United States
(12) Patent Application Publication
(10) Pub. No.: US 2006/0139902 A1
(43) Pub. Date: Jun. 29, 2006

(54) Double-sided component-mounted circuit board and method for manufacturing the same

(75) Inventor: Akihiko Happoya, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Kabushiki Kaisha Toshiba

(21) Appl. No.: 11/317,262

(22) Filed: Dec. 23, 2005

(30) Foreign Application Priority Data
Dec. 28, 2004 (JP) P2004-378819

(51) Int. Cl. H05K 7/08; H05K 7/02; H05K 7/06; H05K 7/10

(52) U.S. Cl. 361/760

(57) ABSTRACT

A double-sided component-mounted circuit board, includes: a base shaped flatly and having a wiring pattern thereon; circuit components mounted on both faces of the base so as to be connected to the wiring pattern to configure a circuit; and a reinforcing member including a contact section that is in contact with a face of the base, and a housing section that houses at least one of the circuit components and that is formed thickness-wise at a position corresponding to the one of the circuit components. The reinforcing member is attached to the face of the base such that the contact section is in contact with the face of the base while circumventing the one of the circuit component at the housing section.

The entire disclosure of Japanese Patent Application No. 2004-378819 filed on Dec. 28, 2004 including specification, claims, drawings and abstract is incorporated herein by reference in its entirety.

### BACKGROUND

1. Field

The present invention relates to a circuit board on both faces of which components are to be mounted, as well as to a method for manufacturing the same. More particularly, the invention relates to a double-sided component-mounted circuit board which can readily suppress, even in a low-profile circuit board having low rigidity, factors for faulty soldering, and the like, which degrade a circuit board, and to a method for manufacturing the same.

2. Description of the Related Art

In a general electronic apparatus, necessary circuitry is formed with use of a printed circuit board on which circuit components are mounted, and the same is housed inside. As a printed circuit board, usually, a rigid printed circuit board is generally employed. However, in an electronic apparatus which requires miniaturization or profile reduction in external shape, to attain the object, there is sometimes employed a measure of reducing an external profile of a board.

To reduce a profile, in the case of a rigid printed circuit board, there is adopted a measure of reducing the thickness of a board material, in addition to lowering the height of circuit components to be mounted.

Meanwhile, a flexible printed circuit board is also conceivable as a printed circuit board. In this case, as a board, there is employed a board having such a thickness as to enable mounting of circuit components.

Also in such a low-profile board, as in the case of the general printed circuit board, leads of circuit components are connected to a wiring pattern formed on the board by way of solder, thereby mounting the circuit components.

However, a low-profile board involves a problem that, due to its low rigidity, the board is prone to be deformed during the course of manufacturing process, thereby causing its wiring pattern to be offset from leads, to thus cause faulty soldering.

In particular, in order to mount circuit components on both faces of a board, circuit components are mounted on one face, and operation for mounting circuit components on the other face is subsequently performed. However, since the circuit components have already been mounted on the opposite face, difficulty is encountered in keeping flat the face which is to be subjected to mounting operation, thereby often rendering operation for mounting the circuit components considerably difficult.

Furthermore, on some occasions, there arise problems; e.g., that handling of the board is difficult even after the circuit components have been mounted, and that a stress caused by deformation of the board is applied on soldered portions, whereby a crack is developed in the solder, causing separation of a joint.

This tendency becomes more pronounced as an area of the board on which components are to be mounted is increased, and as the thickness of the same is reduced.

For this reason, a double-sided component-mounted circuit board is rarely employed in an electronic apparatus. However, if the board can be mounted on an electronic apparatus which requires miniaturization, this can make a major contribution toward attaining miniaturization.

A proposal for reinforcing rigidity of a flexible printed circuit board is disclosed in, e.g., JP-A-9-97954. JP-A-9-97954 discloses a configuration in which a reinforcing plate in which openings are formed in regions corresponding to leads of components is joined to a board. However, since the components are to be mounted on the reinforcing plate, the board is increased in thickness. Accordingly, this configuration cannot be applied to an apparatus which requires profile reduction.

### BRIEF DESCRIPTION OF THE DRAWINGS

Embodiment may be described in detail with reference to the accompanying drawings, in which:

FIG. 1 is a perspective view illustrating an embodiment of a double-sided component-mounted circuit board according to the invention;

FIG. 2 is a perspective view illustrating the circuit board illustrated in FIG. 1 being decomposed into a circuit board main body and a reinforcing plate;

FIG. 3 is a plan view illustrating one face of the circuit board main body illustrated in FIG. 1;

FIG. 4 is a plan view illustrating the other face of the circuit board main body illustrated in FIG. 1;

FIG. 5 is a plan view illustrating the circuit board illustrated in FIG. 1 as viewed from the reinforcing plate;

FIG. 6 is a cross-sectional view illustrating the circuit board illustrated in FIG. 1 as cut away at a line 6-6 in FIG. 5 and viewed from the direction indicated by an arrow;

FIG. 7 is a cross-sectional view for explaining another embodiment of a double-sided component-mounted circuit board according to the invention;

FIG. 8 is a cross-sectional view for explaining still another embodiment of a double-sided component-mounted circuit board according to the invention;

FIG. 9 is a cross-sectional view for explaining yet another embodiment of a double-sided component-mounted circuit board according to the invention;

FIG. 10 is a cross-sectional view for explaining still another embodiment of a double-sided component-mounted circuit board according to the invention;

FIG. 11 is a cross-sectional view for explaining yet another embodiment of a double-sided component-mounted circuit board according to the invention;

FIGS. 12A to 12E are views for explaining an embodiment of a method for manufacturing a double-sided component-mounted circuit board according to the invention; and

FIGS. 13A to 13F are views for explaining another embodiment of a method for manufacturing a double-sided component-mounted circuit board according to the invention.

FIG. 14 is a cross-sectional view for explaining yet another embodiment of a double-sided component-mounted circuit board according to the invention;

### DETAILED DESCRIPTION

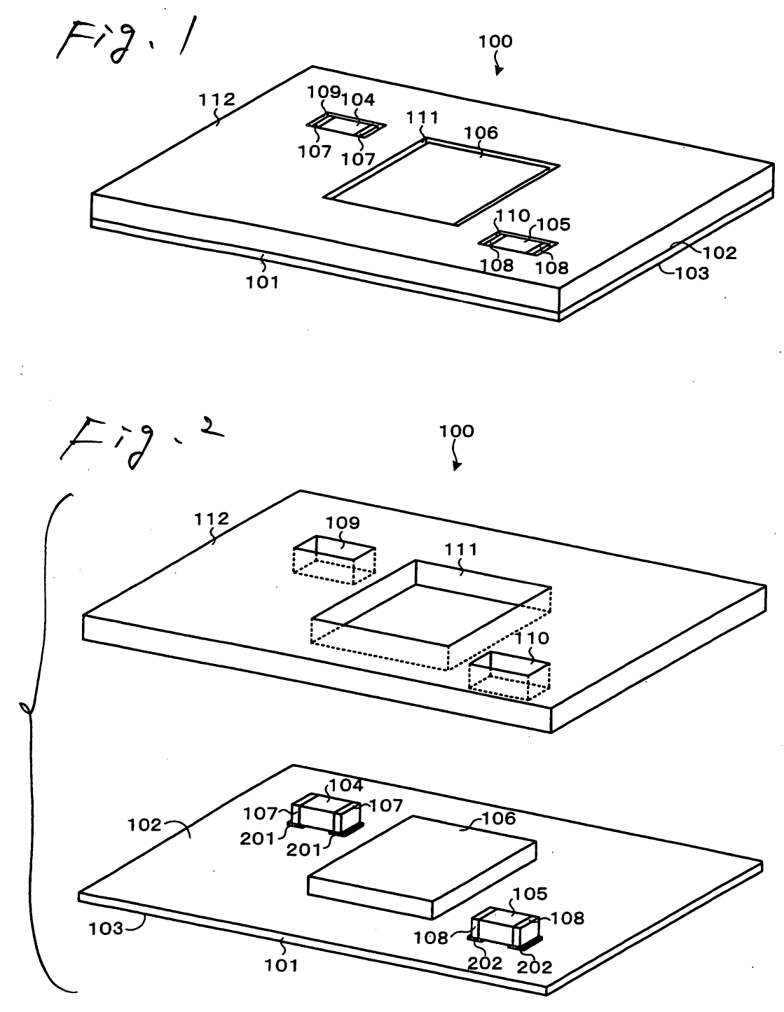

Hereinafter, embodiments of the invention will be described by reference to the drawings in detail. FIG. 1 is a perspective view schematically showing a circuit board 100 configured in accordance with an embodiment of the invention. In FIG. 1, the circuit board 100 is formed into a flat geometry and has a circuit board main body 101.

The circuit board main body 101 has two flat faces 102 and 103. Small circuit components 104 and 105 are mounted on one face 102; and, in addition, a circuit component 106 which is larger in flat-face area is mounted. The circuit component 104 has terminal electrodes 107 at its longitudinal ends; and the circuit component 105 has terminal electrodes 108 at the same. The circuit components 104 and 105 are respectively soldered onto pads of a wiring pattern, which will be described later, by means of the terminal electrode 107 and 108. In addition, electrode sections are formed on an unillustrated face of the circuit component 106 opposing the circuit board 101, and soldered onto pads on the wiring pattern. Thus, the circuit components 104 to 106 are mounted.

In addition, a reinforcing plate 112—which serves as a reinforcing member and in which component housing sections 109, 110, and 111 are formed—is affixed by way of, e.g., an adhesive, to thus be attached on the face 102 of the board main body 101 while circumventing the respective components through employment of the component housing sections 109, 110, and 111. The component housing sections 109, 110, and 111 are formed as openings through the thickness at positions corresponding to the circuit components 104, 105, and 106.

Meanwhile, in FIG. 1, three circuit components are to be mounted. However, FIG. 1 is a schematic illustration for the sake of simplicity of explanation. Accordingly, in actuality, on some occasions, a larger number of circuit components may be mounted. Needless to say, the present embodiment also encompasses such a circuit board.

FIG. 2 illustrates a state in which the circuit board 101 illustrated in FIG. 1 is divided into the board main body 101 and the reinforcing plate 112. As a matter of course, a wiring pattern is formed on the face 102 of the board main body 101. FIG. 2 illustrates, as a portion of the wiring pattern, pads 201 and 202. The terminal electrodes 107 and 108 of the circuit components 104 and 105 are respectively solder-joined to the pads 201 and 202, thereby being mounted on the board main body 101. In addition, as described above, the circuit component 106 is also solder-joined to the pads, thereby being mounted on the board main body 101.

Meanwhile, although not illustrated in FIG. 2, circuit components are mounted also on the other face 103 of the circuit board main body 101.

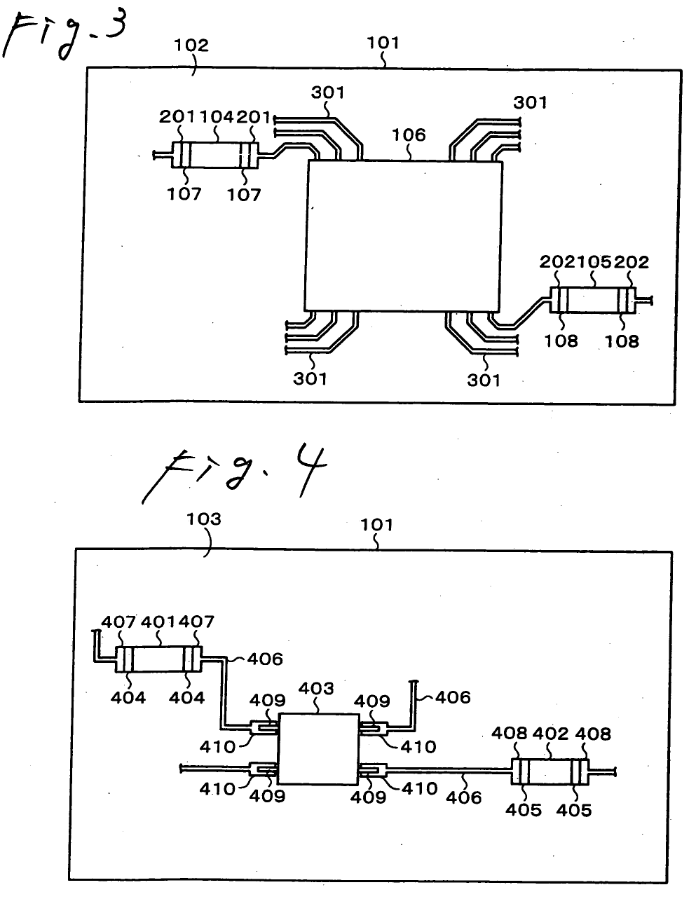

FIG. 3 is a plan view of the face 102 of the circuit board main body 101 on which the circuit components 104 to 106 illustrated in FIG. 2 are mounted. As shown in FIG. 3, a wiring pattern 301 is formed on the face 102. As a portion of the wiring pattern 301, there are formed the pads 201 and 202. The terminal electrodes 107 of the circuit component 104 are soldered onto the pads 201; and the terminal electrodes 108 of the circuit component 105 are soldered onto the pads 202. In addition, unillustrated terminal electrodes of the circuit component 106 are soldered onto unillustrated pads. Meanwhile, FIG. 3 shows the wiring pattern 301 with a portion thereof omitted.

FIG. 4 is a plan view of the face 103 of the circuit board main body 101 opposite to the face 102. As illustrated in FIG. 4, small circuit components 401 and 402, as well as a circuit component 403 which is larger in flat face area, are mounted on the face 103.

The circuit component 401 has terminal electrodes 404 at its longitudinal ends; and the circuit component 402 has terminal electrodes 405 at the same. The circuit components 401 and 402 are respectively soldered onto pads 407 and 408, which are formed as a portion of the wiring pattern formed on the face 103, thereby being mounted on the face 103 of the circuit board main body 101.

Meanwhile, the circuit component 403, which has leads 409, is mounted by means of the leads 409 being soldered onto pads 410 which are formed as a portion of the wiring pattern 406.

Meanwhile, in FIG. 4, three circuit components are to be mounted. However, FIG. 4 is a schematic illustration for the sake of simplicity of explanation. As a matter of course, on some occasions, a wider variety of types of circuit components are mounted in reality. In addition, the wiring pattern 406 is illustrated with a portion thereof omitted.

FIG. 5 is a plane view of the circuit board 100 on which circuit components are mounted as illustrated in FIGS. 1 to 4 as viewed from the reinforcing plate 112. FIG. 6 is a view illustrating the same as cut away at a line 501 consisting of long and short dashes and viewed from the direction indicated by arrows 6-6.

As shown in FIG. 6, the circuit board 100 is configured such that the circuit components 104 to 106 are mounted on the face 102 of the circuit board main body 101. The terminal electrodes 107 and 108 of the circuit components 104 and 105 are respectively joined to the pads 201 and 202 by means of solder 601. In addition, with regard to the circuit component 106, terminal electrodes (not shown) are formed so as to oppose the face 102 of the circuit board main body 101; and the circuit component 106 is mounted to pads 602 disposed on the face 102 of the circuit board main body 101 by means of the solder 601.

Furthermore, the reinforcing plate 112, in which the component housing sections 109 to 111 are formed so as to circumvent the mounted circuit components 104 to 106, is affixed to the face 102 of the circuit board main body 101 by means of an adhesive. The reinforcing plate 112 is formed so as to have a thickness (height) slightly greater than the heights of the mounted circuit components 104 to 106 as measured from the face 102 of the circuit board main body 101. More specifically, there is employed such a configuration that the circuit components 104 to 106 are completely housed in the component housing sections 109 to 111, respectively.

Meanwhile, the reinforcing plate 112 can be formed from a material such as glass epoxy, paper phenol, heat-resistant plastic, or stainless-steel. As an adhesive for affixing the reinforcing plate 112, there is employed an adhesive of a quality capable of resisting heat applied during soldering, such as a heat-resistant adhesive of a thermosetting type.

Meanwhile, the circuit components 401 to 403 are mounted on the face 103 of the circuit board main body 101. The terminal electrodes 404 and 405 of the circuit components 401 and 402 are respectively joined to the pads 407 and 408 by means of the solder 601. In addition, the leads 409 of the circuit component 403 are joined to the pads 410 by means of the solder 601.

Since the circuit board 100 of the invention is configured as above, even when a material having low rigidity is employed as the circuit board main body 101, the reinforcing plate 112 provides reinforcement; whereby there can be provided a circuit board of the same reliability as that of a rigid circuit board having a predetermined rigidity and being capable of suppressing deformation in the face-wise direction by virtue of the rigidity of the material per se.

More specifically, when circuit components are to be mounted on both faces of a circuit board, there are first performed procedures for: applying, e.g., creamy solder, over one face; the circuit components are attached thereon; and mounting the circuit components through reflow soldering. Subsequently, there are also performed similar procedures for: applying creamy solder over the opposite face; attaching circuit components on that face; and mounting the circuit components through reflow soldering. However, when the material of the circuit board has low rigidity, great difficulty is encountered in performing the mounting operation on the second face, after the circuit components have been mounted on the first face, without causing deformation (flexure) of the circuit board main body in the face-wise direction.

As previously mentioned, when a circuit board is deformed, cracks develop at soldered portions, thereby impairing the reliability of mounting of the circuit components. However, the circuit board of the invention is configured such that, after circuit components have been mounted on one face, a reinforcing plate having component housing sections formed so as to circumvent the circuit components is affixed, by means of an adhesive, to the face where the circuit components are mounted. By virtue of the above configuration, deformation of the circuit board main body does not occur during mounting operation of circuit components onto the opposite face of the circuit board, thereby considerably enhancing reliability of the circuit board.

In addition, the thickness of the reinforcing plate 112 is set to be greater than the heights of the circuit components mounted on the face 102 of the circuit board main body 101. Accordingly, at the time of mounting circuit components on the face 103, even when the circuit board main body 101 is placed on a given workbench with the reinforcing plate 112 facing downward, the circuit components do not come into contact with the workbench. Therefore, circuit components can be mounted onto the face 103 without causing deformation of the circuit board main body 101, while maintaining the quality of soldering at a high level.

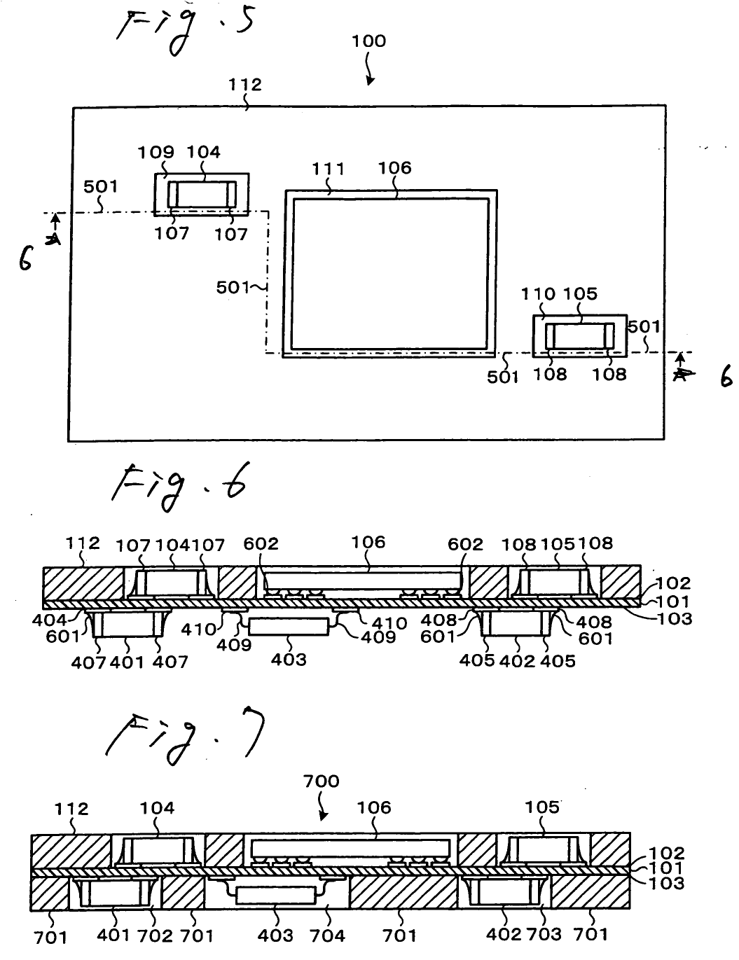

FIG. 7 is a cross-sectional view illustrating another embodiment of the circuit board according to the invention. In FIG. 7, elements identical with those in FIGS. 1 to 6 are denoted by the same reference numerals. In the embodiment illustrated in FIG. 7, a circuit board 700 is configured such that a reinforcing plate 701 is additionally affixed to the face 103 of the circuit board main body 101 of the circuit board 100 illustrated in FIG. 1 to 6, by means of an adhesive or the like. Also in the reinforcing plate 701, component housing sections 702, 703, and 704, each of which is formed as an opening through the thickness, are formed for housing the circuit components 401, 402, and 403, respectively. As is the case of the reinforcing plate 112, the thickness of the reinforcing plate 701 is also set to be greater than heights of the circuit components 401 to 403 mounted on the face 103 of the circuit board main body 101.

In the present embodiment, since the reinforcing plates 112 and 701 are affixed on the two faces 102 and 103 of the circuit board main body 101, respectively, the rigidity of the circuit board main body 101 can be further reinforced, thereby enhancing the quality of the circuit board.

FIG. 8 is a cross-sectional view illustrating still another embodiment of the circuit board of the invention. The present embodiment is characterized in that a circuit board 800 employs such are in forcing plate 801 whose component housing sections 802 are not formed into openings through the thickness, but into a groove-like geometry. Meanwhile, the reinforcing plate 801 may be formed so as to cover the reinforcing plate 112—having been described by reference to FIGS. 1 to 6—in the form of a lid-like member from above. Alternatively, the reinforcing plate 801 may be formed integrally with the reinforcing plate 112.

According to the present embodiment, since the reinforcing plate 801 becomes further resistant to deformation by virtue of its structure, the quality of the circuit board can be further enhanced.

FIG. 9 is a cross-sectional view illustrating still another embodiment of the circuit board according to the invention. A circuit board 900 illustrated in FIG. 9 is configured such that a reinforcing plate is divided into two sections constituted of sections 901 and 902 rather than having such a geometry as to cover the entire face 102 of the circuit board main body 101. The two sections 901 and 902 are respectively attached only to portions of the face 102 of the circuit board main body 101 so as to correspond to portions where the circuit components 104 to 106, and 401 to 403 are mounted. As a result, since portions where no circuit components are mounted are not reinforced by the reinforcing plates 901 and 902, these portions exhibit low rigidity of the inherent circuit substrate main body 101.

In the present embodiment, since the circuit board 900 exhibits low rigidity at portions where no circuit components are mounted, the circuit board main body 101 can be deformed at the portions. FIG. 14 is a cross-sectional view in which the circuit board main body 101 is folded at an intermediate portion where the reinforcing plates 901 and 902 are not disposed. As such, the degree of freedom at the time of mounting the circuit board 900 on a product can be enhanced.

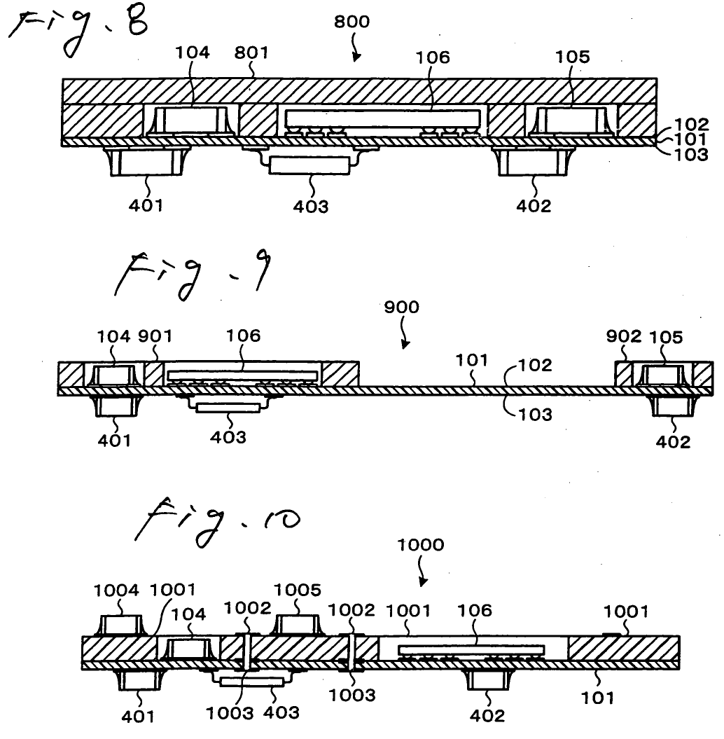

FIG. 10 is a cross-sectional view illustrating yet another embodiment of the circuit board according to the invention. In the embodiment illustrated in FIG. 10, a circuit board 1000 includes a reinforcing plate 1001 formed from a rigid circuit board having a through hole 1002. Alternatively, the reinforcing plate 1001 is formed from a multilayer circuit board. Electrical connection between the reinforcing plate 1001 serving as a circuit board and the circuit board main body 101 can be established by means of, e.g., forming a through hole 1003 also in the circuit board main body 101, and soldering the through holes with each other. Alternatively, since the reinforcing plate 1001 is, by definition, a circuit board, circuit components 1004 and 1005 can be mounted thereon.

The present embodiment can be applied to a circuit board having a complicated circuit configuration.

FIG. 11 is a cross-sectional view illustrating still another embodiment of the circuit board according to the invention. In the embodiment illustrated in FIG. 11, a circuit board 1100 is characterized in that a heat-radiating member 1101 formed from a material having a heat-radiation effect is attached so as to cover the reinforcing plate 112 illustrated in FIG. 1 to 6 from above. At this time, a sheet or grease 1102 for conducting heat to the heat-radiating member 1101 is interposed between the circuit component 106, which in particular releases heat, and the heat-radiating member 1101. Alternatively, the circuit component 106 may be brought into direct contact with the heat-radiating member 1101 without using such sheet or grease 1102. As the heat-radiating member 1101, that formed from a material such as copper, stainless steel, or aluminum can be employed.

According to the present embodiment, the circuit board 1100 can radiate heat released from the mounted circuit components as well as reinforcing the circuit board main body 101. Accordingly, the quality of the circuit board per se can be enhanced, and, furthermore, electrical performance of the circuit can be enhanced.

Next, the manufacturing process of the circuit board of the invention will be described.

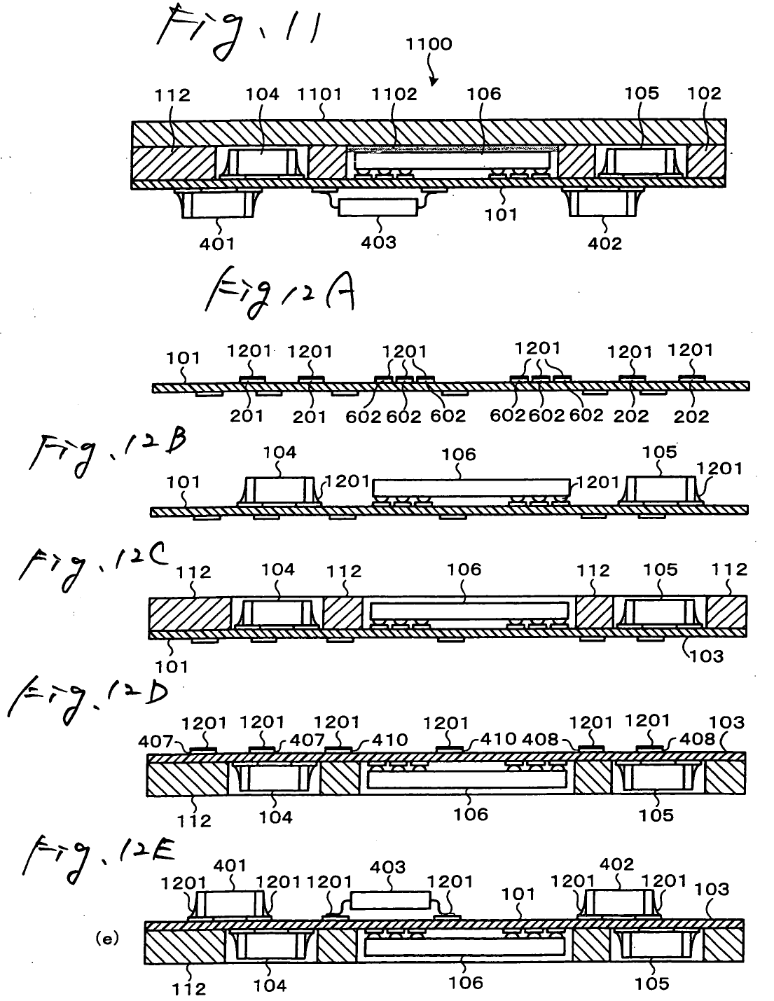

FIGS. 12A to 12E are views for describing an embodiment of a method for manufacturing the circuit board according to the invention.

FIG. 12A shows a state prior to mounting of circuit components. On the face 102 of the circuit board main body 101, creamy solder 1201 is applied to the respective pads 201, 202, and 602 onto which circuit components are to be soldered.

Subsequently, after the circuit components 104 to 106 being attached so as to position the terminal electrodes thereof on pads 201, 202, and 602 where the creamy solder 1201 has been applied, soldering of the terminal electrodes 107 and 108 of the circuit components 104 and 106 to the pads 201 and 202, and soldering of the terminal electrodes of the circuit component 106 to the pads 602 are performed through reflow soldering. FIG. 12B illustrates a state in which the soldering has completed.

Next, as illustrated in FIG. 12C, the reinforcing plate 112 is affixed onto the face 102 of the circuit board main body 101, on which the circuit components 104 to 106 have been mounted, by means of an adhesive. As the adhesive, there can be employed an adhesive of a quality capable of resisting heat applied during soldering, such as a thermosetting, heat-resistant adhesive.

Next, as illustrated in FIG. 12D, the circuit board main body 101 onto which the reinforcing plate 112 is affixed is inverted, and placed on, e.g., a given workbench with the reinforcing plate 112 on the underside. Consequently, the face 103 of the circuit board main body 101 is exposed.

Next, the creamy solder 1201 is applied to the pads 407, 408, and 410 on the face 103 of the circuit board main body 101.

Subsequently, after the circuit components 401 to 403 have been attached so as to position their terminal electrodes 404 and 405 and the leads 409 on pads 407, 408, and 410 where the creamy solder 1201 has been applied; soldering of the terminal electrodes 404 and 405 of the circuit components 401 and 402 to the pads 407 and 408, and soldering of the leads 409 of the circuit component 403 to the pads 410 are performed through reflow soldering. FIG. 12E illustrates a state in which the soldering has been completed. Thus, manufacture of the circuit board 100 is completed.

The above-described method for manufacturing the circuit board 100 according to the invention is configured such that, after circuit components have been mounted on one face 102 of the circuit board main body 101, the reinforcing plate 112 is affixed onto the face 102 while housing the circuit components 104 to 106 in the circuit component housing sections 109 to 111. Accordingly, rigidity of the circuit board main body 101 having low rigidity can be enhanced.

By virtue of this configuration, the circuit board main body 101 is not deformed during the course of performing mounting process of the circuit components 401 to 403 onto the other face 103 of the circuit board main body 101, thereby facilitating the operation. Furthermore, deformation of the circuit board main body 101 during the mounting operation of the circuit components onto the face 103 is suppressed. As a result, mounting operation of the circuit components 401 to 403 can be performed readily and without fail while applying no stress on soldered portions of the circuit components 104 to 106, thereby enhancing the quality of the circuit board.

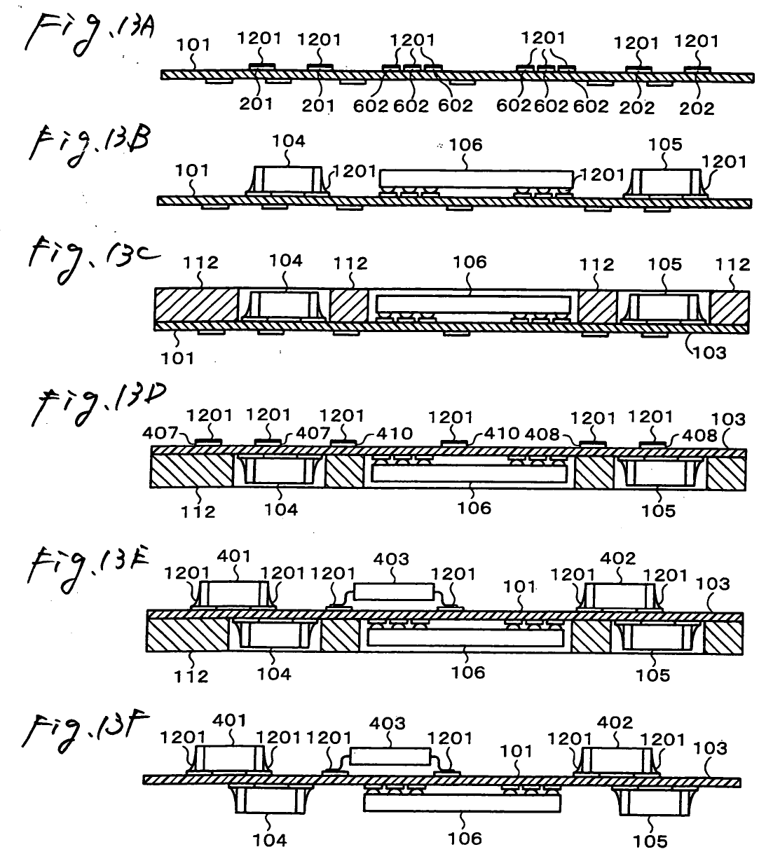

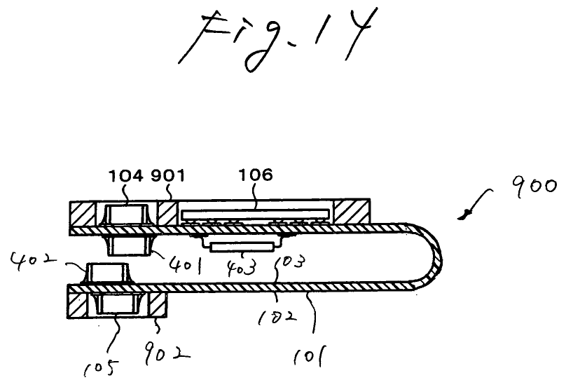

FIGS. 13A to 13F are views illustrating another embodiment of the method for manufacturing the circuit board of the invention. The manufacturing method illustrated in FIGS. 13A to 13F is, as illustrated in FIG. 13F, configured so as to remove the reinforcing plate 112 in a final step. For the purpose of this removal, as an adhesive for use in affixing the reinforcing plate 112 onto the face 102 of the circuit board main body 101, there can be employed a tacky-type heat-resistant adhesive which, even under heat applied during soldering, is not cured and continues to exhibit tackiness. Other processes are identical as those of the manufacturing method shown in FIGS. 12A to 12E.

Since an adhesive having tackiness is employed, a reinforcing plate 112 being affixed can be removed from the face 102 by hand.

According to the present embodiment, stress applied onto soldered portions during the course of manufacture can be suppressed. In addition, the reinforcing plate can be removed after installment of the circuit board in a product or immediately before installment of the same. Furthermore, since the circuit board having been assembled has no reinforcing plate, the geometry of the circuit board can be rendered small and simple.

As described above, the circuit board of the invention is configured such that a reinforcing plate in which circuit component housing sections are formed is affixed onto one face of a circuit board main body while circumventing circuit components by employment of the circuit component housing sections. By virtue of the configuration, the circuit board main body is increased in rigidity, and the circuit board main body is not deformed during the course of mounting circuit components onto the other face. Therefore, no stress is applied onto soldered portions. As a result, mechanical troubles, such as cracks, do not occur in the soldered portions, thereby enabling enhancement of reliability of the circuit board.

Meanwhile, the present invention is not limited to the above-described embodiments, and can be modified in various manners within the scope of the invention.

According to the invention, a reinforcing plate having a housing section which can circumvent circuit components and a contact section to come into contact with a face of a base is attached to at least one face of the base while circumventing the circuit components. As a result, warpage of the base can be prevented, thereby enabling suppression of occurrence of faulty soldering.

What is claimed is:

1. A double-sided component-mounted circuit board, comprising:
a base shaped flatly and having a wiring pattern thereon;
circuit components mounted on both faces of the base so as to be connected to the wiring pattern to configure a circuit; and
a reinforcing member including a contact section that is in contact with a face of the base, and a housing section that houses at least one of the circuit components and that is formed thickness-wise at a position corresponding to the one of the circuit components;
wherein the reinforcing member is attached to the face of the base such that the contact section is in contact with the face of the base while circumventing the one of the circuit component at the housing section.

2. The double-sided component-mounted circuit board according to claim 1,
wherein the reinforcing member is configured such that the contact section is formed on peripheries of the housing section.

3. The double-sided component-mounted circuit board according to claim 1,
wherein the reinforcing member is affixed to the face of the base by an adhesive.

4. The double-sided component-mounted circuit board according to claim 1,
wherein the reinforcing member has outside dimensions corresponding to outside dimensions of the base; and
an entirety of the reinforcing member except the housing section serves as the contact section.

5. The double-sided component-mounted circuit board according to claim 1,
wherein the reinforcing member includes a first member defining the housing section as an opening that penetrates through the first member in a thickness direction, and a second member connected to the first member so as to cover the opening.

6. The double-sided component-mounted circuit board according to claim 5,
wherein the second member is formed from a material of high thermal conductivity; and
the second member is in contact with the one of the circuit components that is housed by the housing sections.

7. The double-sided component-mounted circuit board according to claim 6,
wherein the second member is in direct contact with the one of the circuit components.

8. The double-sided component-mounted circuit board according to claim 6,
wherein the second member is in indirect contact with the one of the circuit components through a heat-conductive material.

9. The double-sided component-mounted circuit board according to claim 1,
wherein the reinforcing member is detachably attached to the base.

10. The double-sided component-mount circuit board according to claim 1,
wherein the reinforcing member includes a circuit board.

11. The double-sided component-mount circuit board according to claim 1,
wherein the reinforcing member includes a multi-layered circuit board.

12. The double-sided component-mounted circuit board according to claim 1,
wherein the base has a low rigidity.

13. The double-sided component-mounted circuit board according to claim 1,
wherein the base has a rigidity that allows the base to be folded.

14. A method for manufacturing a double-sided component-mounted circuit board, comprising:
mounting a circuit component on one face of a base having a wiring pattern thereon, such that the circuit component is connected to the wiring pattern;
attaching a reinforcing member on the base, the reinforcing member including a contact section and a housing section, such that the contact section comes into contact with the face of the base while circumventing the circuit component at the housing section; and
mounting a circuit component on the other face of the base such that the circuit component is connected to the wiring pattern.

15. The method for manufacturing a double-sided component-mounted circuit board according to claim 14, further comprising:
attaching a reinforcing member on the other face of the base, the reinforcing member including a contact section and a housing section, such that the contact section comes into contact with the other face of the base while circumventing the circuit component mounted on the other face of the base at the housing section.

16. The method for manufacturing a double-sided component-mounted circuit board according to claim 14, further comprising:
removing the reinforcing member from the base.

17. The method for manufacturing a double-sided component-mounted circuit board according to claim 14, further comprising:
mounting a circuit component on the reinforcing member such that the circuit component is connected to a wiring pattern formed on the reinforcing member.
